(19) United States
(12) Patent Application Publication
(10) Pub. No.: US 2016/0276298 A1
(43) Pub. Date: Sep. 22, 2016

(54) ARRAY SUBSTRATE AND FABRICATING METHOD THEREOF AS WELL AS DISPLAY DEVICE

(71) Applicants: BOE TECHNOLOGY GROUP CO., LTD., Beijing (CN); HEFEI BOE OPTOELECTRONICS TECHNOLOGY CO., LTD., Hefei (CN)

(72) Inventors: Wei Xue, Beijing (CN); Hongmin Li, Beijing (CN); Xiaohe Li, Beijing (CN); Zhifu Dong, Beijing (CN); Ping Song, Beijing (CN)

(21) Appl. No.: 14/740,208

(22) Filed: Jun. 15, 2015

(30) Foreign Application Priority Data
Mar. 18, 2015 (CN) 201510121491.X

(51) Int. Cl. H01L 23/60; H01L 27/12

(52) U.S. Cl. CPC H01L 23/60; H01L 27/124; H01L 27/1259

(57) ABSTRACT

This disclosure relates to an array substrate and fabricating method thereof as well as a display device, the array substrate comprising: a plurality of scanning lines and a plurality of signal lines, the plurality of scanning lines and plurality of signal lines defining a plurality of pixel regions; and a shielding electrode line arranged above the signal line between adjacent pixel regions, for shielding signal interference between pixel electrodes in the adjacent pixel regions. By means of the technical solution of this disclosure, the shielding electrode line arranged between adjacent pixels can shield crosstalk between the pixel electrodes of adjacent pixels, and can form a transverse storage capacitance with the pixel electrode in the pixel, thereby increasing the total storage capacitance, and maintaining voltage difference between the pixel electrode and a common electrode, so as to diminish the influence of the leakage current and prevent image flicker effectively.

### RELATED APPLICATIONS

The present application claims the benefit of Chinese Patent Application No. 201510121491.X, filed Mar. 18, 2015, the entire disclosure of which is incorporated herein by reference.

### FIELD OF THE INVENTION

This disclosure relates to the field of display technology, specifically, to an array substrate, a display device and a fabricating method of an array substrate.

### BACKGROUND OF THE INVENTION

With the development of productivity and intensified market competition, high PPI (Pixels Per Inch) products have become the requirement and mainstream direction of the market. The increase of the PPI and the improvement of the resolution will result in sharp decline of the sizes of the pixels and sub-pixels (dot). The lessening of the sub-pixels may result in the following:

The distance between two adjacent pixel electrodes becomes small, thereby crosstalk between the pixel electrodes occurs more easily;

The overlapping area of the pixel electrode and the common electrode becomes small, such that the storage capacitance of the pixel becomes small. With the increase of the leakage current (Ioff) during the operation, the smaller storage capacitance cannot maintain the voltage difference between the pixel electrode and the common electrode, thereby resulting in image flicker.

The method of increasing storage capacitance in the prior art is generally adding scanning lines as the common electrode lines, as shown in FIG. 1. Such a design has two disadvantages:

Firstly, there is an organic film between the added common electrode lines and the pixel electrodes, so that less capacitance is increased;

Secondly, because the scanning lines are not light transmissive, the aperture opening ratio of the whole sub-pixel is reduced, thereby resulting in decrease of the light transmittance.

### SUMMARY OF THE INVENTION

The technical problems to be solved by this disclosure are how to reduce the signal interference between the pixel electrodes in adjacent pixels, and how to increase storage capacitance of the pixel.

For this purpose, this disclosure proposes an array substrate, comprising:

a plurality of scanning lines and a plurality of signal lines, the plurality of scanning lines and plurality of signal lines defining a plurality of pixel regions; and

a shielding electrode line, arranged above the signal line between adjacent pixel regions, for shielding signal interference between pixel electrodes in the adjacent pixel regions.

In an embodiment, the array substrate may further comprise:

an insulating layer, arranged above the signal line,

wherein the shielding electrode line is arranged in a region above the insulating layer corresponding to the signal line.

In an embodiment, the width of the shielding electrode line may be greater than or equal to the width of the signal line.

In an embodiment, the materials of the shielding electrode line and the common electrode of the pixel region may be same.

In an embodiment, the shielding electrode line and the common electrode of the pixel region may be formed through a same process.

In an embodiment, the array substrate may further comprise:

a first lead for providing an electric signal for the shielding electrode line; and

a second lead for providing an electric signal for the common electrode.

In an embodiment, the electric signal provided by the first lead for the shielding electrode line may be same as the electric signal provided by the second lead for the common electrode.

In an embodiment, the distances from the shielding electrode line to the pixel electrode in each pixel region in the adjacent pixel regions may be equal.

This disclosure further proposes a display device, comprising any of the above array substrate.

This disclosure further proposes a fabricating method of an array substrate, comprising:

forming a plurality of scanning lines and a plurality of signal lines, which plurality of scanning lines and plurality of signal lines define a plurality of pixel regions; and

forming a shielding electrode line above the signal line between adjacent pixel regions, so as to shield signal interference between pixel electrodes in the adjacent pixel regions.

In an embodiment, the method may further comprise:

forming an insulating layer above the signal line,

and the step of forming the shielding electrode line may comprise:

forming the shielding electrode line in a region above the insulating layer corresponding to the signal line.

In an embodiment, the width of the shielding electrode line may be greater than or equal to the width of the signal line.

In an embodiment, the materials of the shielding electrode line and the common electrode of the pixel region may be same.

In an embodiment, the shielding electrode line may be formed at the same time of forming the common electrode of the pixel region.

In an embodiment, the method may further comprise:

forming electrically isolated first lead and second lead, which first lead provides an electric signal for the shielding electrode line and which second lead provides an electric signal for the common electrode.

In an embodiment, the electric signal provided by the first lead for the shielding electrode line may be same as the electric signal provided by the second lead for the common electrode.

In an embodiment, the distances from the shielding electrode line to the pixel electrode in each pixel region in the adjacent pixel regions may be equal.

By means of the technical solution of this disclosure, the shielding electrode line arranged between adjacent pixels can shield crosstalk between the pixel electrodes of the adjacent pixels, and can form a transverse storage capacitance with the pixel electrode in the pixel, thereby increasing the total storage capacitance, and maintaining voltage difference between the pixel electrode and the common electrode, so as to diminish the influence of the leakage current during the operation and prevent image flicker effectively.

### BRIEF DESCRIPTION OF DRAWINGS

The characteristics and the advantages of this disclosure will be understood more clearly by making reference to the drawings, the drawings are schematic and should not be construed as any limitation to this disclosure, in the drawings:

FIG. 1 shows a structural schematic view of an array substrate with added scanning lines in the prior art;

FIG. 2 shows a structural schematic view of an array substrate according to an embodiment of this disclosure;

FIG. 3 is a schematic flow chart of a fabricating method of an array substrate according to an embodiment of this disclosure.

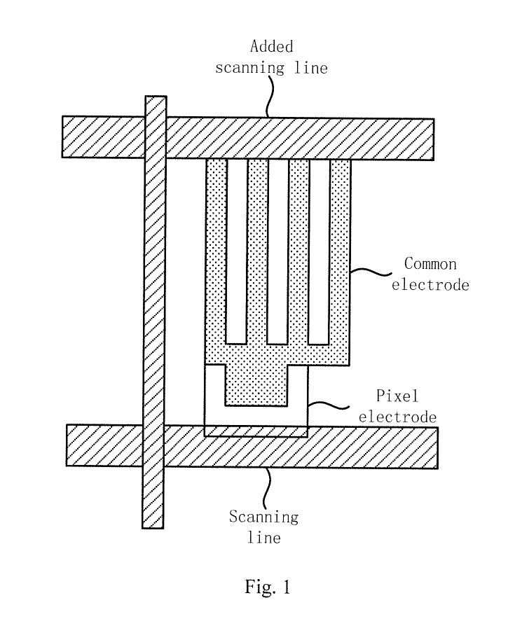

### EXPLANATIONS OF REFERENCE SIGNS

1—scanning line; 2—signal line; 3—shielding electrode line; 4—pixel electrode; 5—common electrode.

### DETAILED DESCRIPTION OF THE INVENTION

In order to understand the above purposes, characteristics and advantages of this disclosure more clearly, next, this disclosure will be described in detail further in combination with the drawings and the specific implementing modes. It should be noted that in the case of not conflicting, the embodiments and the features in the embodiments of this disclosure can be combined with one another.

Many specific details are elaborated in the following description for the convenience of understanding this disclosure sufficiently, however, this disclosure can also be implemented using other modes different from what is described here. Therefore, the protection scope of this disclosure is not limited by the specific embodiments disclosed in the following.

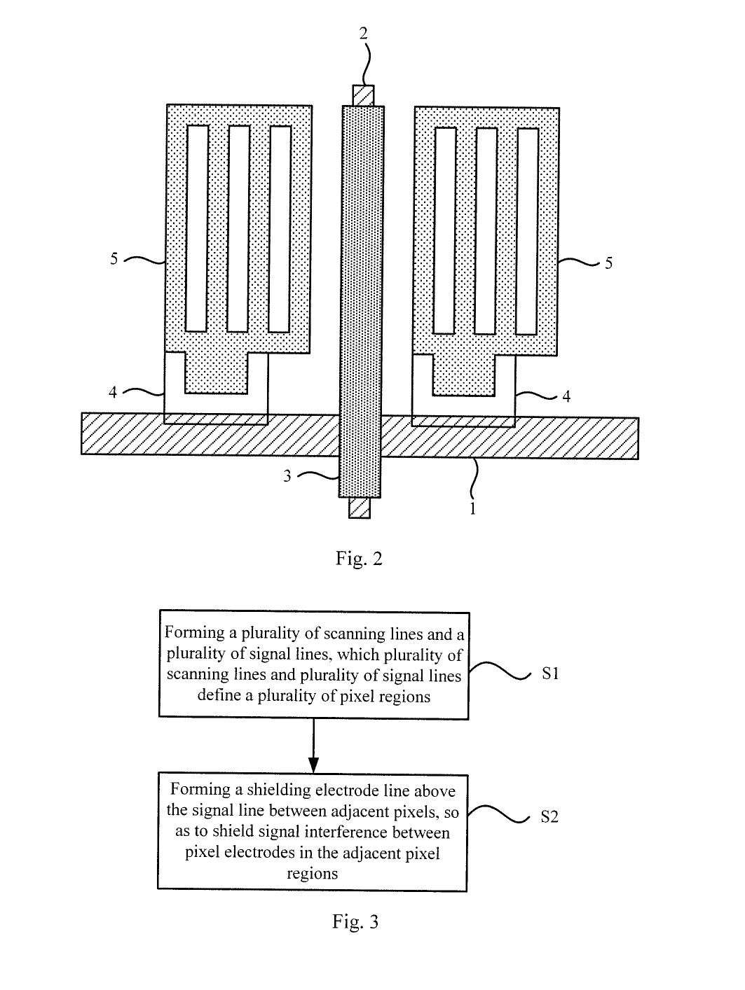

As shown in FIG. 2, an array substrate according to an embodiment of this disclosure, comprises:

a plurality of scanning lines 1 (i.e., gate lines) and a plurality of signal lines 2, the plurality of scanning lines 1 and the plurality of signal lines 2 defining a plurality of pixel regions; and

a shielding electrode line 3, arranged above the signal line 2 between adjacent pixel regions, for shielding signal interference between pixel electrodes 4 in the adjacent pixel regions.

The shielding electrode line 3 is arranged between adjacent pixel regions, which can isolate crosstalk between the pixel electrodes in two adjacent pixels effectively.

The shielding electrode line 3 can also form a transverse storage capacitance with the pixel in each of the adjacent pixel regions, so as to increase the total storage capacitance of the pixel structure, and maintain voltage difference between the pixel electrode and the common electrode in each pixel region, thereby diminishing the influence of the leakage current during the operation and preventing image flicker effectively.

It should be noted that the conventional structures of the array substrate such as a source, a drain, an active layer, a passivation layer and so on also exist in the array substrate proposed in this disclosure, which are merely not shown in FIG. 3, and will not be repeated here.

The array substrate may further comprise:

an insulating layer, arranged above the signal line 2,

wherein the shielding electrode line 3 is arranged in a region above the insulating layer corresponding to the signal line 2.

By arranging an insulating layer, electrical isolation between the shielding electrode line 3 and the signal line 2 can be ensured, the current in the signal line 2 will not influence the shielding electrode line 3.

The width of the shielding electrode line 3 may be greater than or equal to the width of the signal line 2.

In this way, it can be ensured that the shielding electrode line 3 shields the signal line 2 completely and the shielding electrode line 3 has a relatively small resistance.

It should be noted that in order to show the relative positional relationship and the width relationship between the shielding electrode line 3 and the signal line 2 clearly, the signal line 2 comes out at the two ends of the shielding electrode line 3 in FIG. 3. Actually, the shielding electrode line 3 can be set equal to or longer than the signal line 2, and shield the signal line 2 completely. The specific length and width of the shielding electrode line 3 can be selected and set based on requirements, which will not be repeated here.

The materials of the shielding electrode line 3 and the common electrode 5 of the pixel region may be same.

The shielding electrode line 3 may use transparent conductive materials, so as to increase aperture opening ratio of the array substrate while ensuring conduction.

The shielding electrode line 3 and the common electrode 5 of the pixel region may be formed through a same process.

In this way, the number of the processes of forming the array substrate can be reduced, thereby simplifying the fabricating flow of the array substrate, and not needing to change the original wiring mode in the array substrate.

The array substrate may further comprise:

a first lead for providing an electric signal for the shielding electrode line 3; and

a second lead for providing an electric signal for the common electrode 5.

The electrically isolated first lead and second lead, by supplying power to the shielding electrode line 3 and the common electrode 5 respectively, can provide different or same electric signal for the shielding electrode line 3 and the common electrode 5 respectively (the specific situation can be set based on requirements), thereby ensuring the shielding electrode line 3 to play a better shielding effect to the pixel electrodes 4 in the adjacent pixel regions, and increasing storage capacitance of the pixel, such that the pixel electrode 4 can drive the transistor better with the common electrode 5.

The electric signal provided by the first lead for the shielding electrode line 3 may be same as the electric signal provided by the second lead for the common electrode 5.

The shielding electrode line 3 in this embodiment is arranged between adjacent pixel regions, which as a whole is equivalent to adding in the display region a plurality of electrode lines perpendicular to the scanning lines 1. When providing the same electric signal to the shielding electrode line 3 as the common electrode 5, the shielding electrode line 3 can play the function of a common electrode line, i.e., equivalent to adding in the display region a plurality of common electrode lines perpendicular to the scanning lines 1. In this way, the common electrode lines arranged at the frame of the display region in the prior art can be narrowed or even removed, thereby reducing the frame width, which is benefit for realizing narrow frames.

The distances from the shielding electrode line 3 to the pixel electrode 4 in each pixel region in the adjacent pixel regions may be equal.

This disclosure further proposes a display device, comprising any of the above array substrate.

It should be noted that the display device in this embodiment may be any product or component with the display function such as electronic paper, mobile phone, tablet computer, television, laptop, digital photo frame, navigator and the like.

This disclosure further proposes a fabricating method of an array substrate, comprising:

In step S1, forming a plurality of scanning lines 1 and a plurality of signal lines 2, which plurality of scanning lines 1 and plurality of signal lines 2 define a plurality of pixel regions; and

In step S2, forming a shielding electrode line 3 above the signal line 2 between adjacent pixel regions, so as to shield signal interference between pixel electrodes 4 in the adjacent pixel regions.

The method may further comprise:

forming an insulating layer above the signal line 2,

and the step of forming the shielding electrode line 3 may comprise:

forming the shielding electrode line 3 in a region above the insulating layer corresponding to the signal line 2.

The width of the shielding electrode line 3 may be greater than or equal to the width of the signal line 2.

The materials of the shielding electrode line 3 and the common electrode 5 of the pixel region may be same.

The shielding electrode line 3 may be formed at the same time of forming the common electrode 5 of the pixel region.

The method may further comprise:

forming a first lead and a second lead, which first lead provides an electric signal for the shielding electrode line 3 and which second lead provides an electric signal for the common electrode 5.

The first lead and the second lead may be formed in the same process, and may also be formed in different processes. The operation of forming the first lead and the second lead may be performed before or after the common electrode 5 is formed, which is determined based on the requirement of the specific process.

The electric signal provided by the first lead for the shielding electrode line 3 may be same as the electric signal provided by the second lead for the common electrode 5.

The distances from the shielding electrode line 3 to the pixel electrode 4 of each pixel region in the adjacent pixel regions may be equal.

The forming process adopted in the above flow for example may comprise: film forming processes such as depositing, sputtering, and patterning processes such as etching.

The technical solutions of this disclosure have been explained in detail above in combination with the drawings, considering that in the prior art, in order to improve PPI, crosstalk may easily occur between the pixel electrodes in adjacent pixels, and the storage capacitance of the pixel may be reduced, thereby resulting in image flicker. By means of the technical solutions of this disclosure, the shielding electrode line arranged between adjacent pixels can shield crosstalk between the pixel electrodes of adjacent pixels, and can form a transverse storage capacitance with the pixel electrode in the pixel, thereby increasing total storage capacitance, and maintaining voltage difference between the pixel electrode and the common electrode, so as to diminish the influence of the leakage current, and prevent image flicker effectively.

It should be pointed out that the sizes of the layers and regions might be magnified in order to figure clearly in the drawings. Moreover, it could be understood that when it is claimed that an element or a layer is “above” another element or layer, it may be above the other element or layer directly, or a middle element or layer may exist between them. In addition, it could be understood that when it is claimed that an element or a layer is “under” another element or layer, it may be under the other element or layer directly, or a middle element or layer may exist between them. In addition, it could also be understood that when it is claimed that a layer or an element is “between” two layers or two elements, it may be the unique layer between the two layers or the unique element between the two elements, or there may also be more than one middle layers or elements. The similar reference signs throughout the text indicate similar elements.

In this disclosure, the term “first”, “second” are only used for describing, and cannot be understood as indicating or implying relative importance. The term “a plurality of” refers to two or more than two, except for additional explicit definitions.

What are stated above are merely preferred embodiments of this disclosure, which are not used to limit this disclosure. For the skilled person in the art, this disclosure may have various modifications and changes. Any amendment, equivalent replacement, improvement made within the spirit and principle of this disclosure all should be covered within the protection scope of this disclosure.

1. An array substrate comprising:
a plurality of scanning lines and a plurality of signal lines, the plurality of scanning lines and plurality of signal lines defining a plurality of pixel regions; and
a shielding electrode line, arranged above the signal line between adjacent pixel regions, for shielding signal interference between pixel electrodes in the adjacent pixel regions.

2. The array substrate according to claim 1, further comprising:
an insulating layer, arranged above the signal line,
wherein the shielding electrode line is arranged in a region above the insulating layer corresponding to the signal line.

3. The array substrate according to claim 2, wherein the width of the shielding electrode line is greater than or equal to the width of the signal line.

4. The array substrate according to claim 1, wherein the materials of the shielding electrode line and a common electrode of the pixel region are same.

5. The array substrate according to claim 4, wherein the shielding electrode line and the common electrode of the pixel region are formed through a same process.

6. The array substrate according to claim 5, further comprising:
a first lead for providing an electric signal for the shielding electrode line; and
a second lead for providing an electric signal for the common electrode.

7. The array substrate according to claim 6, wherein the electric signal provided by the first lead for the shielding electrode line is same as the electric signal provided by the second lead for the common electrode.

8. The array substrate according to claim 1, wherein the distances from the shielding electrode line to the pixel electrode in each pixel region in the adjacent pixel regions are equal.

9. A display device comprising an array substrate, wherein the array substrate comprises:
a plurality of scanning lines and a plurality of signal lines, the plurality of scanning lines and plurality of signal lines defining a plurality of pixel regions; and
a shielding electrode line, arranged above the signal line between adjacent pixel regions, for shielding signal interference between pixel electrodes in the adjacent pixel regions.

10. A fabricating method of an array substrate, comprising:
forming a plurality of scanning lines and a plurality of signal lines, which plurality of scanning lines and plurality of signal lines define a plurality of pixel regions; and
forming a shielding electrode line above the signal line between adjacent pixel regions, so as to shield signal interference between pixel electrodes in the adjacent pixel regions.

11. The fabricating method according to claim 10, further comprising:
forming an insulating layer above the signal line;
and wherein the step of forming the shielding electrode line comprises:
forming the shielding electrode line in a region above the insulating layer corresponding to the signal line.

12. The fabricating method according to claim 11, wherein the width of the shielding electrode line is greater than or equal to the width of the signal line.

13. The fabricating method according to claim 10, wherein the materials of the shielding electrode line and the common electrode of the pixel region are same.

14. The fabricating method according to claim 13, wherein the shielding electrode line is formed at the same time of forming the common electrode of the pixel region.

15. The fabricating method according to claim 14, further comprising:
forming a first lead and a second lead, which first lead provides an electric signal for the shielding electrode line and which second lead provides an electric signal for the common electrode.

16. The fabricating method according to claim 15, wherein the electric signal provided by the first lead for the shielding electrode line is same as the electric signal provided by the second lead for the common electrode.

17. The fabricating method according to claim 10, wherein the distances from the shielding electrode line to the pixel electrode in each pixel region in the adjacent pixel regions are equal.
